(19) United States
(12) Patent Application Publication
(10) Pub. No.: US 2026/0251715 A1
(43) Pub. Date: Aug. 27, 2026

(54) METHOD FOR ESTIMATING THE STATE OF CHARGE OF AN ELECTROCHEMICAL ELEMENT AND ASSOCIATED DEVICES

(71) Applicant: SAFT, LEVALLOIS PERRET (FR)

(72) Inventors: Daniel MONIER-REYES, AVENSAN (FR); Nicolas DUFOUR, SAINT-REMY LES CHEVREUSE (FR); Gérard BARRAILH, MONEIN (FR)

(73) Assignee: SAFT, LEVALLOIS PERRET (FR)

(21) Appl. No.: 18/860,854

(22) PCT Filed: May 2, 2023
(86) PCT No.: PCT/EP2023/061481

§ 371 Date: Oct. 28, 2024

(30) Foreign Application Priority Data
May 3, 2022 (FR) 22 04190

(51) Int. Cl. G01R 31/367; G01R 31/374; G01R 31/3842; H01M 10/42

(52) U.S. Cl. CPC G01R 31/367; G01R 31/374; G01R 31/3842; H01M 10/425; H01M 10/4285; H01M 2010/4271

(57) ABSTRACT

The present invention relates to a method for estimating the state of charge of at least one electrochemical element of a battery, the method being implemented by a computer, the computer storing a state of charge estimation model, estimating from a voltage value, a current value, a temperature value and a capacity value of the at least one electrochemical element, the value of the state of charge of the at least one electrochemical element, the state of charge estimation model being a learned neural network.

### CROSS REFERENCE TO RELATED APPLICATIONS

The present application is a U.S. National Phase Application under 35 U.S.C. § 371 of International Patent Application No. PCT/EP2023/061481 filed May 2, 2023, which claims priority of French Patent Application No. 22 04190 filed May 3, 2022. The entire contents of which are hereby incorporated by reference.

### FIELD OF THE INVENTION

The present invention relates to a method for estimating the state of charge of at least one electrochemical element in a battery. The present invention also relates to an associated computer, management system and battery.

### BACKGROUND

Typically, a battery comprises one or more current accumulators, also known as electrochemical generators, cells or elements. An accumulator is an electricity generating device in which chemical energy is converted into electrical energy. The chemical energy comes from electrochemically active compounds deposited on at least one face of electrodes arranged in the accumulator. Electrical energy is generated by electrochemical reactions during a battery discharge. The electrodes, arranged in a container, are electrically connected to current output terminals which ensure electrical continuity between the electrodes and an electrical consumer with which the accumulator is associated.

### SUMMARY

In order to increase the electrical power delivered, several sealed accumulators can be combined to form a battery. Thus, a battery can be divided into modules, each module being composed of one or more accumulators connected together in series and/or parallel. Thus, a battery may, for example, include one or more parallel branches of series connected accumulators and/or one or more parallel branches of series connected modules.

A charging circuit is usually provided, to which the battery can be connected to recharge the accumulators.

Furthermore, an electronic management system comprising measurement sensors and an electronic control circuit, more or less advanced according to the application, can be associated with the battery. In particular, such a system allows to organize and control the charging and discharging of the battery, in order to balance the charging and discharging of the various accumulators in the battery relative to each other.

The state of charge is a useful piece of information for the electronic battery management system, to optimize its use and service life. The state of charge is often referred to as SOC.

To acquire the state of charge SOC, two calculation techniques are known to be used, based on continuous measurements of voltage, current and temperature trends.

The first technique can be described as “coulometric”, in that it makes use of the fact that the state of charge SOC depends on the load (Ampere hour count) and on the battery capacity Q.

In fact, the following formulae apply:

$$SOC = {SOC}_{0} + \frac{{\int }_{0}^{t} I \times dt}{Q}$$

Where SOC₀ is the initial value of the SOC at instant t=0.

However, this first technique is highly sensitive to current measurement error as well as the capacity estimation. As a result, using this technique alone leads to an accumulation of current measurement error, resulting in an erroneous state of charge estimate.

The second technique is based on the open circuit voltage OCV measurements and uses a pre-established mapping table to acquire the state of charge SOC as a function of the open circuit voltage. The open circuit voltage is often referred to as OCV.

Since the function linking the open circuit voltage OCV to the state of charge SOC is a function of the voltage minus the product of resistance and current, the second technique is sensitive to resistance estimation. Thus, it is therefore advisable to use the second technique under conditions allowing to minimize the error on the resistance, that is, under quiescent or low-current conditions.

It is known to use the two above-mentioned techniques by using the first technique as usual and regularly recalibrating the state of charge SOC using the second technique.

However, in some electrochemical elements, because the variation of the open circuit voltage as a function of the state of charge SOC presents a plateau, the correspondence between the open circuit voltage OCV and the state of charge SOC may be false.

Thus, it is known to perform a reset by recharging with a state of charge SOC higher than the maximum state of charge SOC corresponding to the end of the plateau.

Such a technique generally requires the interruption of the mission of the electrochemical element in order to carry out the recharge. This is particularly the case for frequency regulation missions involving cycles on the plateau. Such interruptions can be incompatible with the mission.

There is therefore a need for a method of estimating the state of charge SOC of an electrochemical element that is more accurate and feasible during normal operation of the electrochemical element.

To this end, the description describes a method for estimating the state of charge of at least one electrochemical element of a battery, the method being implemented by a computer, the computer storing a state of charge estimation model estimating from a voltage value, a current value, a temperature value and a capacity value of the at least one electrochemical element, the value of the state of charge of the at least one electrochemical element, the state of charge estimation model being a learned neural network, the method comprising, for a plurality of instants, the steps of:
acquisition of values for the voltage, current, temperature and capacity of the at least one electrochemical element,
calculation of value of the state of charge of the at least one electrochemical element according to a first technique and a second technique,
the first technique including the following operations:
acquisition of an estimated value of the state of charge acquired at a previous time,
calculation of the value of the quantity of charge accumulated since the previous instant, using the current values acquired,
deduction of a first calculated value of the state of charge by calculating the sum of the estimated value of the state of charge acquired at the previous instant and the ratio of the value of the quantity of charge accumulated since the previous instant and the value of the capacity of the at least one electrochemical element,
the second technique including the following operations
application of the state of charge estimation model to the values acquired for the current, the temperature and the capacity of the at least one electrochemical element at the same instant of acquisition, and to a voltage value depending on the value acquired for the voltage of the at least one electrochemical element at the same instant of acquisition, to acquire a second calculated state of charge value,
comparison of the difference in absolute value between the second calculated value and the first calculated value with the absolute value of a threshold, and
when the difference in absolute value between the second calculated value and the first calculated value is less than or equal to the threshold, determination of the estimated state of charge value as being the second calculated state of charge value,
or
when the difference in absolute value between the second calculated value and the first calculated value is strictly greater than the threshold, determination of the estimated value of the state of charge, as being the sum of the first calculated value of the state of charge and a correction factor proportional to the threshold.

According to particular embodiments, the estimation method presents one or more of the following features, taken singly or in any technically possible combination:
the correction factor is equal to the product of a coefficient, a direction value and the threshold, the direction value being equal to the ratio between the difference of the second calculated value and the first calculated value and the absolute value of the difference of the second calculated value and the first calculated value, the coefficient advantageously being between 1 and 2;
the threshold depends on the maximum current bias, the maximum current bias taking into account at least one contribution selected from the list constituted of a first contribution coming from a current sensor supplying the current values, a second contribution coming from the self-discharge of the at least one electrochemical element and a third contribution coming from errors in the estimation of the capacity of the at least one electrochemical element;
the method further includes a threshold determination step, the threshold being equal to the ratio between the value of the quantity of charge likely to be accumulated since the previous instant as a result of the maximum current bias and the value of the capacity of the at least one electrochemical element;
the voltage value depending on the acquired voltage value of the at least one electrochemical element at the same instant of acquisition is the acquired voltage value of the at least one electrochemical element at the same instant of acquiring;
the method further includes a step of estimating the steady state voltage value at the instant of acquisition, the voltage value depending on the acquired voltage value of the at least one electrochemical element at the same instant of acquisition being the estimated steady state voltage value;
the estimation step is implemented by applying a steady state voltage estimation model to the voltage value of the at least one electrochemical element at the instant of acquisition, the current value of the at least one electrochemical element at the instant of acquisition and the time elapsed since the previous instant;
the neural network is a multilayer perceptron;
the neural network includes a number of neurons less than or equal to 100;
the estimated initial value of the state of charge is chosen from among predefined values and the second calculated value;
the at least one electrochemical element presenting an open circuit state of charge voltage characteristic with a flat portion, a flat portion being a portion in which the open circuit voltage variation is less than 30 mV for a variation of at least 10% in the state of charge;
the at least one electrochemical element comprises an active cathode material selected from the following groups or mixtures thereof:
i) a compound of the formula LiₓFe_{1-y}M_{y}PO₄ where M is chosen from the group consisting of B, Mg, Al, Si, Ca, Ti, V, Cr, Mn, Co, Ni, Cu, Zn, Y, Zr, Nb and Mo; and 0.8≤x≤1.2; 0≤y≤0.6,
ii) a compound of formula LiₓMn_{1-y-z}M′_{y}M″_{z}PO₄, where M′ and M″ are different from each other and are chosen from the group consisting of B, Mg, Al, Si, Ca, Ti, V, Cr, Fe, Co, Ni, Cu, Zn, Y, Zr, Nb and Mo, with 0.8≤x≤1.2; 0≤y≤0.6; 0.0≤z≤0.2,
iii) a compound of formula LiₓMn_{2-y-z}Ni_{y}M_{z}O_{4-d-c}F_{c} where M represents one or more elements chosen from the group consisting of B, Mg, Al, Si, Ca, Ti, V, Cr, Fe, Co, Cu, Zn, Y, Zr, Nb, Ru, W and Mo; and 1≤x≤1.4; 0<y≤0.6; 0≤z≤0.2; 0≤d≤1; 0≤c≤1,
iv) a compound of the formula LiₓMn_{2-y-z}M′_{y}M″_{z}O₄, where M′ and M″ are chosen from the group consisting of B, Mg, Al, Si, Ca, Ti, V, Cr, Fe, Co, Ni, Cu, Zn, Y, Zr, Nb and Mo; M′ and M″ being different from each other, and 1≤x≤1.4; 0≤y≤0.6; 0≤z≤0.2, and
v) a compound of the formula LiVPO₄F.

The description also proposes a computer able to estimate the state of charge of at least one electrochemical element of a battery,
the computer storing a state of charge estimation model, estimating from a voltage value, a current value, a temperature value and a capacity value of the at least one electrochemical element the value of the state of charge of the at least one electrochemical element, the state of charge estimation model being a learned neural network,
   the computer being, for several instants, able to:
      acquire values for the voltage, the current, the temperature and the capacity of the at least one electrochemical element,
      calculate the value of the state of charge of the at least one electrochemical element according to a first technique and a second technique,
   the first technique including the following operations:
      acquisition of an estimated value of the state of charge acquired at a previous instant,
      calculation of the value of the quantity of charge accumulated since the previous instant, using the current values acquired,
      deduction of a first calculated value of the state of charge by calculating the sum of the estimated value of the state of charge acquired at the previous instant and the ratio of the value of the quantity of charge accumulated since the previous instant and the value of the capacity of the at least one electrochemical element,
   the second technique including the following operations:
      applying the state of charge estimation model to the values acquired for the current, the temperature and the capacity of the at least one electrochemical element at the same instant of acquisition, and to a voltage value depending on the value acquired for the voltage of the at least one electrochemical element at the same instant of acquisition, to acquire a second calculated state of charge value, and
      comparing the difference in absolute value between the second calculated value and the first calculated value with a threshold, and
      when the difference in absolute value between the second calculated value and the first calculated value is less than or equal to the threshold, determine the estimated state of charge value, as being the second calculated state of charge value,
   or
      when the difference in absolute value between the second calculated value and the first calculated value is strictly greater than the threshold, determine the estimated value of the state of charge, as being the sum of the first calculated value of the state of charge and a correction factor proportional to the threshold.

The description also describes a management system for at least one electrochemical element of a battery, the at least one electrochemical element presenting terminals, the management system comprising:
a voltage sensor able to measure the voltage at the terminals of said at least one electrochemical element,
a current sensor able to measure the current delivered by said at least one electrochemical element,
a temperature sensor able to measure the temperature of said at least one electrochemical element, and
a computer as previously described. The description also proposes a battery comprising:
at least one electrochemical element, and
a management system as described above.

In the present description, the expression “able to” means indifferently “adapted for”, “suitable for” or “configured for”.

### BRIEF DESCRIPTION OF THE DRAWINGS

Further features and advantages of the invention will become apparent from the following description, given solely by way of non-limiting example, and made with reference to the appended drawings, in which:

FIG. 1 is a schematic representation of an example of a battery including an electrochemical element,

FIG. 2 is a graph illustrating an example of the state of charge open circuit voltage characteristic of the electrochemical element of FIG. 1,

FIG. 3 is a block diagram representing an example of the implementation of a method for estimating the state of charge of the electrochemical element,

FIGS. 4 to 7 are experimental graphs involved in the implementation of certain steps of the method for estimating described in FIG. 3 or in a method of the state of the art,

FIG. 8 is a block diagram representing another example of the implementation of the method for estimating the state of charge of an electrochemical element and

FIG. 9 is a graph presenting the time variation of voltage in an electrochemical element.

### DETAILED DESCRIPTION

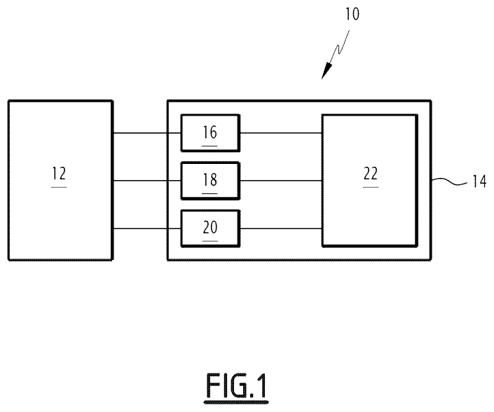

A battery 10 is shown in FIG. 1.

In a manner known per se, a battery is generally an arrangement of a plurality of electrochemical elements, but for the sake of simplicity, a case with a single electrochemical element is described below, in the knowledge that transposition to other arrangements is immediate.

The battery 10 includes an electrochemical element 12 and a management system 14 for the electrochemical element 12.

As previously explained, an electrochemical element 12 is an electricity generating device in which chemical energy is converted into electrical energy.

The electrochemical element 12 therefore delivers a current and a voltage between two terminals.

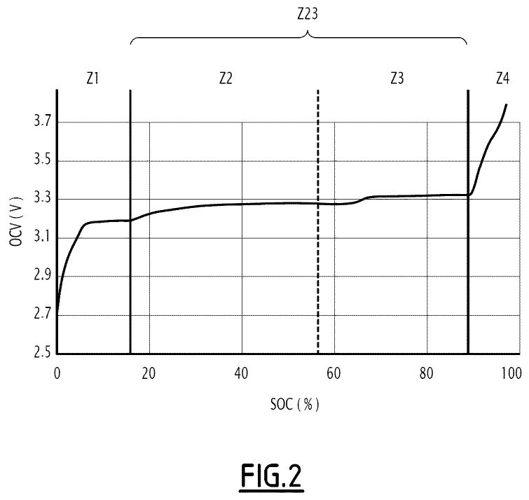

The electrochemical element 12 has a state of charge SOC open circuit voltage OCV characteristic, such as seen in FIG. 2, which is referred to as the characteristic SOC/OCV in the following.

In FIG. 2, the state of charge SOC is expressed as a percentage of a state of maximum charge.

The SOC/OCV characteristic presents four zones, a first zone Z1, a second zone Z2, a third zone Z3 and a fourth zone Z4.

The first zone Z1 corresponds to the start of charging and the fourth zone Z4 to the end of charging.

For the two intermediate zones, insofar as the second zone Z2 and third zone Z3 correspond to a flat portion, it will be useful to name the flat portion Z23 in the following.

The flat portion Z23 is a portion in which the open circuit voltage OCV variation is less than 30 mV for a variation of at least 10% in the state of charge SOC.

This type of SOC/OCV characteristic is found, in particular, when the electrochemical element 12 is an electrochemical element comprising a cathode active material selected from the following groups or mixtures thereof:
i) a compound of the formula LiₓFe_{1-y}M_{y}PO₄ where M is chosen from the group consisting of B, Mg, Al, Si, Ca, Ti, V, Cr, Mn, Co, Ni, Cu, Zn, Y, Zr, Nb and Mo; and 0.8≤x≤1.2; 0≤y≤0.6,
ii) a compound of the formula LiₓMn_{1-y-z}M′_{y}M″_{z}PO₄, where M′ and M″ are different from each other and are chosen from the group consisting of B, Mg, Al, Si, Ca, Ti, V, Cr, Fe, Co, Ni, Cu, Zn, Y, Zr, Nb and Mo, with 0.8≤x≤1.2; 0≤y≤0.6; 0≤z≤0.2,
iii) a compound of the formula LiₓMn_{2-y-z}Ni_{y}M_{z}O_{4-d-c}F_{c} where M represents one or more elements chosen from the group consisting of B, Mg, Al, Si, Ca, Ti, V, Cr, Fe, Co, Cu, Zn, Y, Zr, Nb, Ru, W and Mo; and 1≤x≤1.4; 0<y≤0.6; 0≤z≤0.2; 0≤d≤1; 0≤c≤1,
iv) a compound of the formula LiₓMn_{2-y-z}M′_{y}M″_{z}O₄, where M′ and M″ are chosen from the group consisting of B, Mg, Al, Si, Ca, Ti, V, Cr, Fe, Co, Ni, Cu, Zn, Y, Zr, Nb and Mo; M′ and M″ being different from each other, and 1≤x≤1.4; 0≤y≤0.6; 0≤z≤0.2, and
v) a compound of the formula LiVPO₄F.

The anode active material is not particularly limited. It is a material capable of having lithium inserted into its structure. It can be chosen from among lithium compounds, carbonaceous materials such as graphite, coke, carbon black and glassy carbon. It can also be based on tin, silicon, carbon-silicon compounds, carbon-tin compounds or carbon-tin-silicon compounds. It can also be a lithium titanium oxide such as Li₄Ti₅O₁₂ or a niobium titanium oxide such as TiNb₂O₇.

Of course, these examples are non-limiting and the method described hereinafter can be used for any type of electrochemical element 12, and in particular when the calculation of its state of charge SOC classically relies on a coulometric counter that may diverge and/or a recalibration involving a rest time and a low current.

The management system 14 is a system able to manage the electrochemical element 12.

The management system 14 includes a voltage sensor 16, a current sensor 18, a temperature sensor 20 and a computer 22.

The voltage sensor 16 is able to measure the voltage across the electrochemical element 12 terminals.

The current sensor 18 is able to measure the current delivered by the electrochemical element 12.

The temperature sensor 20 is able to measure the temperature of the electrochemical element 12.

The computer 22 is able to implement a method for estimating the state of charge of the electrochemical element 12.

The computer 22 is an electronic circuit designed to manipulate and/or transform data represented by electronic or physical quantities in the computer registers and/or memories into other similar data corresponding to physical data in register memories or other types of display devices, transmission devices or storage devices.

As specific examples, the computer 22 comprises a single-core or multi-core processor (such as a central processing unit (CPU), a graphics processing unit (GPU), a microcontroller and a digital signal processor (DSP), a programmable logic circuit, such as an application-specific integrated circuit (ASIC), a field programmable gate array (FPGA), a programmable logic device (PLD) and programmable logic arrays (PLA), a state machine, a logic gate and discrete hardware components.

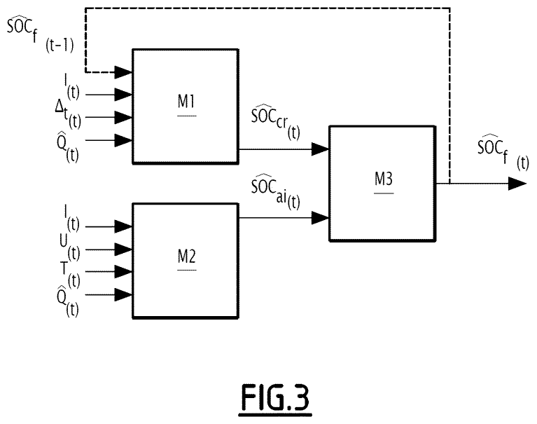

An example of the implementation of the state of charge SOC estimation process is now described with reference to the block diagram representation in FIG. 3.

As will become apparent from the following description, the method involves the use of three models, a first model M1, a second model M2 and a third model M3.

A model is defined here as the mathematical tool corresponding to a technique for measuring or estimating a physical quantity. The technique is thus a step in a measurement or estimation method that takes measurements as input and gives as output a value representative of the physical quantity, while the model takes numerical values as input and outputs other numerical values. It is the technique that gives physical meaning to these numerical values.

The method thus allows to estimate the state of charge SOC of the electrochemical element 12 using a hybrid model (the third model M3) involving, on the one hand, a model calculating the state of charge SOC using coulometric counting (the first model M1) and, on the other hand, a model calculating the state of charge SOC using a neural network (the second model M2). The third model M3 is used to limit inaccuracies in the determination of the state of charge SOC due to the bias of the current sensor 18, the self-discharge of the electrochemical element 12 as well as the faulty estimation of the capacity of the electrochemical element.

It may be noted that, of these three models M1, M2 and M3, only the second model M2 is a learned neural network. Thus, the state of charge SOC estimation method comprises two phases, a learning phase and a use phase.

According to the example described, the learning phase is implemented off-line, in other words, the learning phase is not embedded.

It is during this learning phase that the second M2 model is trained to learn how to estimate a state of charge from constant current charge and discharge profiles for different temperatures and different states of ageing (several elements having different capacities due to ageing).

In the example described, the learning phase includes a neural network learning step, a calculation step and a setting step.

During the learning step, the neural network is trained to estimate the state of charge SOC of the electrochemical element 12 from the values of voltage of the electrochemical element 12, current of the electrochemical element 12, temperature of the electrochemical element 12 and capacity Q of the electrochemical element 12.

The voltage, the current and the temperature values come from the voltage sensor 16, the current sensor 18 and the temperature sensor 20 respectively.

According to the example described, these values are measured regularly.

The capacity value Q is acquired less frequently and can be acquired by any technique, in particular by determination during a full charge or discharge.

The neural network to be trained is a multilayer perceptron.

Such a neural network is more often referred to by the abbreviation MLP, which stands for “multilayer perceptron”.

A neural network is thus an ordered succession of layers of neurons, each of which takes its input from the output of the previous layer.

More precisely, each layer comprises neurons taking their inputs from the outputs of the neurons in the previous layer.

In the example, the layers are dense, in other words, a neuron in one layer takes inputs from all the neurons in the previous layer. This type of layer is sometimes referred to as “fully connected”.

Each layer is linked by a plurality of synapses. A synaptic weight is associated with each synapse. This is usually a real number that can take on both positive and negative values.

Each neuron is able to perform a weighted sum of the value(s) received from the neurons of the preceding layer with a possible bias specific to each neuron, each value then being multiplied by the respective synaptic weight, then by applying an activation function, typically a non-linear function, to said weighted sum, and delivering to the neurons of the following layer the value resulting from the application of the activation function. The activation function allows non-linearity to be introduced into the processing performed by each neuron. Examples of activation functions are the sigmoid function, the hyperbolic tangent function and the Heaviside function.

The neural network to be trained is a neural network that can be easily embedded.

Thus, the neural network should present a limited number of neurons.

For example, the total number of neurons in the neural network is of the order of several tens of neurons, or a maximum of a hundred neurons.

In the example described, the neural network comprises several layers, namely an input layer, one or more hidden layers and an output layer.

The neural network is trained using a supervised learning technique.

Thus, it involves training the free parameters of the neural network from a dataset acquired from real laboratory experiments, typically for between 20 and 40 different electrochemical elements.

During these experiments, the electrochemical elements 12 undergo successive cycles, and the electrical values of these electrochemical elements 12 (current, voltage, state of charge SOC, capacity) and temperature values are recorded to form the data set.

The data set is then separated into a training set and a test set, according to a ratio of 80%-20%, for example.

The training set is used so that the neural network learns its various free parameters by successive iterations until it verifies a desired performance criterion. The result is a learned neural network.

The test set is then used to evaluate the performance of the learned neural network.

The neural network thus constitutes, for the electrochemical element 12, a second model M2 estimating a state of charge value SOC from the voltage, the current, the temperature and the capacity values.

The second model M2 is rather robust to even strong current biases, due to its structure based on a multilayer perceptron that is memory effect free, in other words, it uses only current values and not previous values to acquire the desired estimate.

Furthermore, because of its small size, the second model M2 is easy to embed, as its memory footprint and processor footprint are reduced.

Nevertheless, this means that such a second model M2 presents an estimation error, in other words, a deviation between the estimated value and the actual value, relatively large under certain conditions.

The neural network of the second model M2 is loaded into a memory of the computer 22.

The computer 22 is thus ready to implement the utilization phase.

Unlike the learning phase, which is carried out only once, the utilization phase is implemented for a plurality of instants.

In particular, the utilization phase corresponds to a real time utilization phase of the battery 10.

For example, the instants are equally spaced, for example by a time interval of between 100 milliseconds (ms) and 2 seconds(s).

According to another example, the duration between two instants is not constant.

The steps of the utilization phase are implemented for each instant.

In this sense, it can thus be considered that the utilization phase is iterative, that at each instant of implementation an iteration takes place.

According to the example described, the utilization phase is implemented online, in other words, the utilization phase is embedded and therefore implemented by the computer 22.

The utilization phase includes an acquisition step, a calculation step, a threshold determination step, a comparison step and a step for determining the estimated value of the state of charge.

During the acquisition step, the computer 22 acquires measurements (values) of the voltage U, the current I, the temperature T and the capacity Q of the electrochemical element 12.

During the calculation step, the computer 22 calculates the value of the state of charge SOC according to two distinct techniques corresponding to the first model M1 and the second model M2.

According to a first technique, the computer 22 performs the so-called coulometric technique presented above.

This technique is based on the fact that the state of charge SOC of an electrochemical element 12 depends directly on the ratio between the quantity of charge accumulated (or Ampere hours count in reference to the unit often used for this quantity) and the capacity of the electrochemical element 12.

Thus, the computer 22 uses the current values and the capacity value according to the following formula:

$$\text{?} = \text{?} + \frac{{\int }_{t - 1}^{t} I \times dt}{Q}$$

Where:
t−1 designates a previous instant,
[symbol] designates the estimated value of the state of charge SOC acquired at the present instant t, and
[symbol] designates the estimated value of the state of charge SOC acquired at the previous instant t−1.

More precisely, the first technique includes three operations, an acquisition operation, a calculation operation and a deduction operation.

During the acquisition operation, the computer 22 acquires an estimated value [symbol] of the state of charge SOC, this value having been acquired at a previous instant t−1.

Then, during the calculation operation, the computer 22 calculates the value of the quantity of charge accumulated since the previous instant t−1, using the values of the current acquired.

This accumulated quantity of charge ΔAh₍ₜ₎ is the differential in ampere hours with respect to the previous instant t−1, according to the relationship:

$$Δ A {h}_{( t )} = \frac{{I}_{( t )} * {Δ}_{{t}_{( t )}}}{3600}$$

In this relationship, Δₜ_{₍ₜ₎} designates the duration of the time interval elapsed since the previous instant t−1.

The computer 22 then deduces a first calculated value of the state of charge by calculating the sum of the estimated value of the state of charge SOC acquired and the ratio of the value of the quantity of charge accumulated between the previous instant t−1 and the current instant t and the estimated value of the capacity \hat{Q}₍ₜ₎ of the at least one electrochemical element.

Noting the first calculated value [symbol] , it thus gives:

$$\text{?} = \text{?} + \frac{Δ A {h}_{( t )} * 100}{{\hat{Q}}_{( t )}} = \text{?} + \frac{\frac{{I}_{( t )} * {Δ}_{{t}_{( t )}}}{3 \; 600} * 100}{{\hat{Q}}_{( t )}}$$

The computer 22 thus acquires a value for the state of charge SOC according to the first technique, in other words, the first calculated value [symbol] .

According to the second technique, the second estimation model M2 allows to calculate a state of charge from the measurement of the temperature T₍ₜ₎, the voltage U₍ₜ₎, the electrochemical element capacity \hat{Q}₍ₜ₎ and the current I₍ₜ₎ applied to the electrochemical element 12.

In other words, the computer 22 applies the second estimation model M2 to the voltage value U, the current value I, the temperature value T and the capacity value Q acquired in the acquisition step at the same instant of acquisition.

This is equivalent to making an inference using the off-line learned neural network to acquire a value for the state of charge SOC.

Thus, the computer 22 acquires a value for the state of charge SOC according to the second technique, referred to as the second calculated value [symbol] .

At the end of the calculation step, the computer 22 thus has two distinct values for the state of charge SOC of the electrochemical element 12, namely [symbol] and [symbol] ;

During the determination step of the threshold S, the computer 22 determines the threshold S.

This threshold S depends on the maximum current bias I_{bias_max(t)}, in other words, the various contributions to the imperfections in determining the state of charge SOC due to the fact that the current will drift over time.

To determine this value of the maximum current bias I_{bias_max(t)}, one or more contributions can be taken into account.

A first contribution to the current bias comes from the imperfections of the current sensor 18 supplying the values of the current. This first contribution is noted as I_{biais_capteur_max(t)}.

A second contribution to the current bias comes from a physical phenomenon, namely the self discharge of the electrochemical element 12. This second contribution is noted as I_{autodécharge_max(t)}.

A third contribution to the current bias comes from the errors in estimating the capacity of the electrochemical element 12. This third contribution is noted as I_{biais_capacité_max(t)}.

The third contribution comes from the error in estimating the capacity when acquiring the latter (for example, during a maintenance cycle by making a complete discharge and counting the Ampere hours), the result acquired is accurate to within a quantity of Ampere hours (the quantity may be negative or positive). This quantity in Ampere hours can be related to a current as if the electrochemical element 12 were discharging at a higher or lower current than that measured by the current sensor 18.

For example, starting from a state of charge of 100%, a complete discharge at a given current will lead to reaching the state of charge of 0% earlier if the capacity is underestimated or later if the capacity is overestimated, which can be reduced to a current differential (bias) corresponding to I_{biais_capacité_max(t)}.

When all three contributions are taken into account, the following relationship arises:

$${I}_{bias \_ max ( t )} = \vert {I}_{biais \_ capteur \_ max ( t )} \vert + \vert {I}_{{autod é harge}_{-} max ( t )} \vert + \vert {I}_{biais \_ capacit é \_ max ( t )} \vert$$

Each of the three contributions is, for example, known from the data coming from the manufacturer.

In the example described, the computer 22 determines the threshold S as the ratio between the value of the quantity of charge likely to be accumulated since the previous instant as a result of the maximum current bias and the value of the capacity of the electrochemical element 12.

It thus follows that the threshold S here is a state of charge equivalent of the value of the maximum current bias, in other words:

$$S = Δ {SOC}_{bias \_ max ( t )} = \frac{Δ {Ah}_{bias \_ max ( t )} * 100}{{\hat{Q}}_{( t )}}$$

In this expression, ΔAh_{bias_max(t)} designates the differential in Ampere hours, this quantity being able to be calculated from the maximum current bias I_{bias_max(t)} and the time elapsed Δₜ_{₍ₜ₎} since the previous estimation (expressed in seconds) as follows:

$$Δ {Ah}_{bias \_ max ( t )} = \frac{{I}_{bias \_ max ( t )} * {Δ}_{{t}_{( t )}}}{3600}$$

As a result, the threshold S can be expressed as:

$$S = \frac{\frac{{I}_{bias \_ max ( t )} * {Δ}_{{t}_{( t )}}}{3 \; 600} * 100}{{\hat{Q}}_{( t )}}$$

During the comparison step, the computer 22 compares two quantities, namely, on one hand, the difference in absolute value between the second calculated value and the first calculated value [symbol] − [symbol] , and, on the other hand, the absolute value of the threshold S calculated in the previous step.

The comparison thus allows two cases to be determined:
a first case according to which the difference in absolute value between the second calculated value [symbol] and the first calculated value [symbol] is less than or equal to the threshold S, in other words:

$$\vert \text{?} - \text{?} \vert \leq \vert Δ {SOC}_{{MaxBias}_{( t )}} \vert$$

a second case according to which the difference in absolute value between the second calculated value [symbol] and the first calculated value [symbol] is strictly greater than the threshold S, in other words:

$$\vert \text{?} - \text{?} \vert > \vert Δ {SOC}_{{MaxBias}_{( t )}} \vert$$

During the determination step, the computer 22 determines the estimated value of the state of charge [symbol] differently according to the case acquired in the comparison step.

When the computer 22 is in the presence of the first case, the computer 22 determines the estimated value of the state of charge [symbol] as being the second calculated value [symbol] , which is written mathematically as:

$$\text{?} = \text{?}$$

When the computer 22 is in the presence of the second case, the computer 22 determines the estimated value of the state of charge [symbol] as being the sum of the first calculated value of the state of charge [symbol] and a correction factor proportional to the threshold S.

In this case, the correction factor is equal to the product of a coefficient, a direction value and the threshold, namely:

$${f}_{c o r r} = C * S * D$$

Where:
f_{corr} designates the correction factor,
D designates the direction value, this value being equal to the ratio between the difference of the second calculated value [symbol] , and the first calculated value [symbol] and the absolute value of the difference of the second calculated value [symbol] and the first calculated value [symbol] , which is written mathematically as:

$$D = \frac{\text{?} - \text{?}}{\vert \text{?} - \text{?} \vert}$$

the direction value D thus taking two values +1 or −1, and
C designates a coefficient, which is advantageously between 1 and 2 and is adapted as a function of the conditions of use of the method (see the example of initialization described below).

Taking account of these definitions, the correction factor f_{corr} satisfies the following mathematical relationship:

$${f}_{c o r r} = \frac{\text{?} - \text{?}}{\vert \text{?} - \text{?} \vert} * C * Δ {SOC}_{{MaxBias}_{( t )}}$$

For advantageous values of the coefficient C, that is, when the coefficient is between 1 and 2, this means that:

$$Δ {SOC}_{{MaxBias}_{( t )}} \leq \vert {f}_{c o r r} \vert \leq 2 * Δ {SOC}_{{MaxBias}_{( t )}}$$

The operation just described implies feedback with an earlier instant, which will generally be the previous instant.

The question then arises of how to set the values at the first instant, since no value has been estimated at the previous instant.

For this purpose, the present method proposes an initialization step.

During the initialization step, the computer 22 sets the initial capacity of the electrochemical element 12 and the initial estimated value of the state of charge of the electrochemical element 12.

In the following, the initial capacity of the electrochemical element 12 is noted \hat{Q}₍ₜ₌₀₎ or Qᵢₙᵢₜ and similarly, the initial estimated value of the state of charge of the electrochemical element 12 is noted [symbol] or SOCᵢₙᵢₜ.

The initial capacity Qᵢₙᵢₜ is acquired by the computer 22 by an estimate from a known model, for example, or by a predefined datum.

With regard to the initial estimated value of the state of chargeSOCᵢₙᵢₜ, the computer 22 chooses either predefined values or the second calculated value [symbol] (which implies that the first technique will be implemented after the second technique in this case).

More precisely, in the example described, the computer 22 chooses:
a value of 100% after a maintenance cycle ending with a full charge,
the second value calculated [symbol] when the electrochemical element 12 is not experiencing an overly dynamic current setpoint episode. It can be considered that the current no longer presents a dynamic character from the moment the voltage of the electrochemical element 12 has reached a steady state. Such a value is generally supplied by the manufacturer of the electrochemical element 12,
the value given by the voltage on condition of a low current setpoint and a certain rest time for the electrochemical element 12, these low current and rest time data also being supplied by the manufacturer of the electrochemical element 12, and
a value of 50% otherwise.

Even if the initial estimated value of the state of charge SOCᵢₙᵢₜ is wrong, it is possible to quickly correct the estimated value by increasing the value of the coefficient C, so that it has a value well above 2, for example 5. The value of the coefficient C will then be brought back into the preferred range (between 1 and 2 here) to ensure good accuracy of the state of charge SOC estimate.

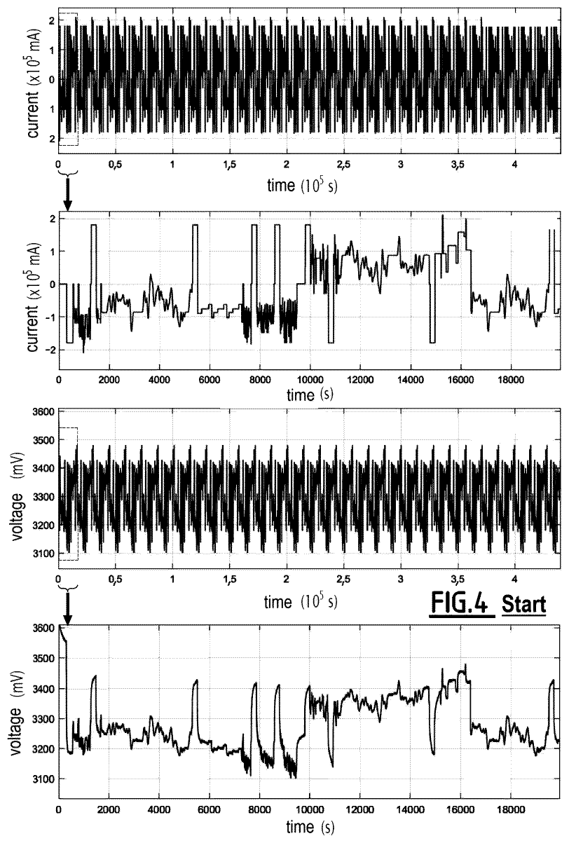

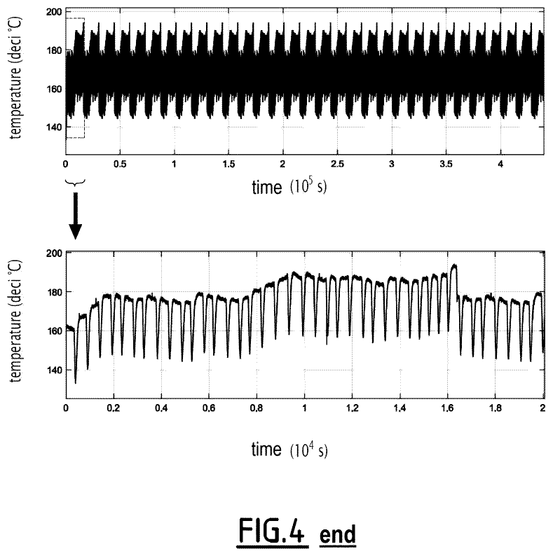

Reference is now made to FIGS. 4 to 7 for examples of experimental implementation of the method just described by the applicant.

FIG. 4 presents the input data, namely the dynamic current over 440,000 seconds (5.1 days), the voltage of the electrochemical element 12 and the temperature of the electrochemical element 12.

In each case, the entire graph is presented, with an enlargement of part of this entire graph.

Furthermore, the capacity is the measured capacity Q, that is, 196 Ah in this example.

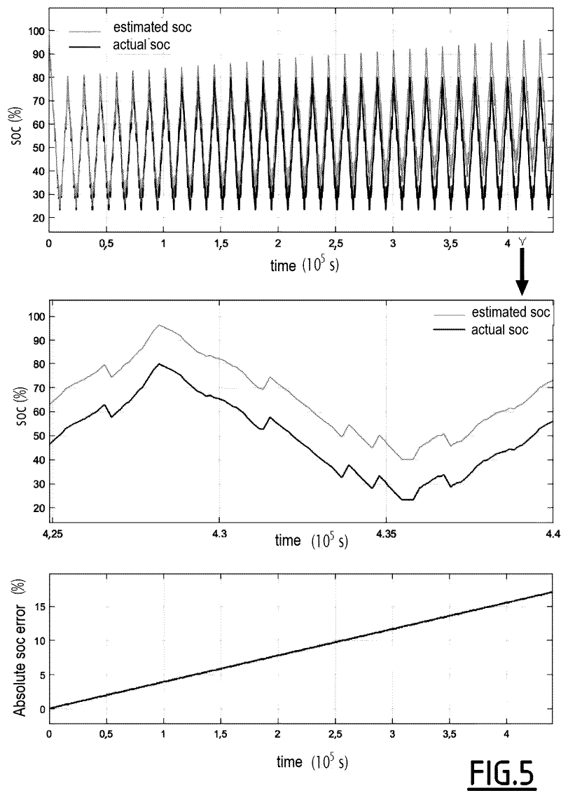

FIG. 5 presents the results acquired by implementation of a coulometric technique.

In this case, a current bias of 300 mA is artificially injected. This injection is done by adding this bias to the measured experimental value. The value of 300 mA has been chosen as it corresponds to a classic bias for current sensors.

The 300 mA current bias is injected during the 440,000 seconds of the experiment, assuming that the initial state of charge is correct.

At the top of FIG. 5, the time variation between the actual value of the state of charge and the value acquired by implementation of the coulometric technique is represented. As before, this variation is represented on the entire graph, as well as on an enlarged section.

At the bottom of FIG. 5, the estimation error for the state of charge is represented. This error increases linearly with time, reaching 18.7% after 440,000 seconds (5.1 days).

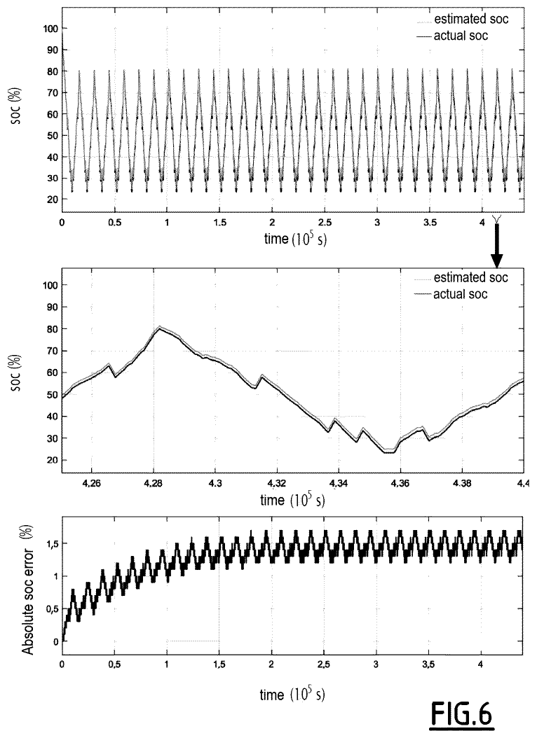

FIG. 6 presents the results acquired by implementing the method of FIG. 3. The assumptions are the same as for the case in FIG. 5.

At the top of FIG. 6, the time variation between the actual value of the state of charge and the value acquired by implementing the method in FIG. 3 is represented. As before, this variation is represented on the entire graph, as well as on an enlarged section.

At the bottom of FIG. 6, it is the estimation error on the state of charge that is represented. This error always remains contained, at a maximum of 1.7%. The gain is clear relative to the case illustrated in FIG. 5.

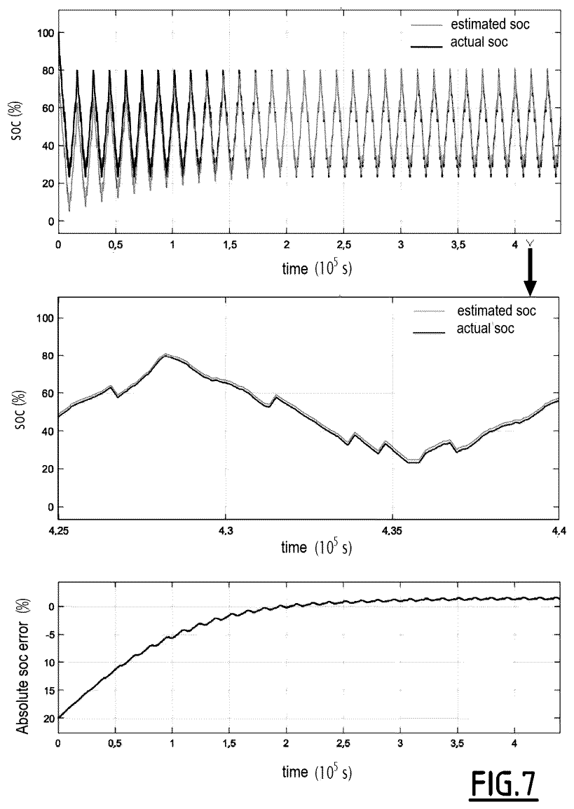

FIG. 7 presents the results acquired by implementing the method of FIG. 3. The assumptions are the same as for the case in FIG. 5, except that it is assumed that an error in the initial value of the state of charge is present (here 20% error).

The graphs represented are the same as for FIG. 6. It can be observed that the error is gradually compensated for, reaching a value of 1.7% at the end of 440,000 seconds.

Such a method therefore allows to estimate the value of the state of charge SOC of the electrochemical element 12 with greater accuracy.

Indeed, the method corresponds to the use of a hybrid model using two distinct techniques: a first technique from the world of measurement, based on coulometric counting, and a second technique from the world of machine learning, based on the application of a neural network.

The method just described is based on a compass effect.

In this analogy, the second calculated value [symbol] serves as a reference direction, and the force with which the first calculated value [symbol] must be modified is proportional to the value of the maximum current bias I_{bias_max(t)}.

The method can thus be interpreted as a correction of the coulometric technique by the compass effect.

It should be noted that this gain in accuracy is acquired with a relatively low computational overhead, as the neural network used presents a very small memory footprint (few neurons). This means that the gain in accuracy remains compatible with an embedded application.

Furthermore, the method also allows permanent recalibration of the first technique to be performed while the electrochemical element 12 is in normal use, even in the flat portion Z23. This thus allows the electrochemical element 12 to continue its mission while having a good estimation of the state of charge SOC. This results in improved availability of the electrochemical element 12 and/or avoids oversizing the battery 10.

Other embodiments with the above-mentioned advantages are also conceivable.

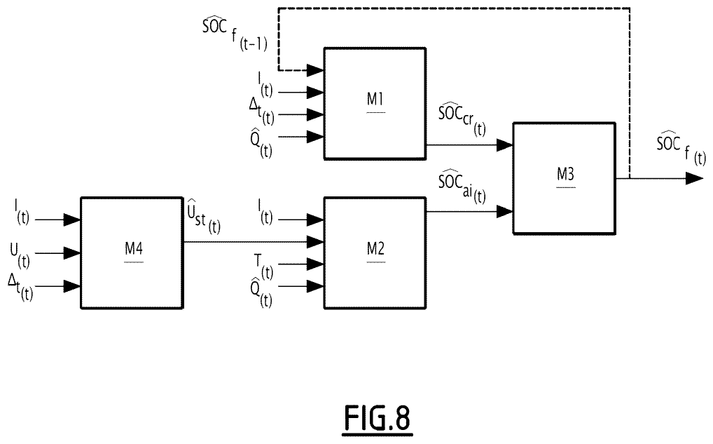

A further embodiment, in particular, is described in FIG. 8.

In this FIG. 8, it can be seen that the estimation method is based on the three aforementioned models M1, M2 and M3 and a fourth model M4.

The fourth model M4 is a model for pre-processing an input from the second model M2.

Specifically, instead of providing the voltage of the electrochemical element 12 as an input to the second model M2, the fourth model M4 provides an estimated value of the steady state voltage Ûₛₜ_{₍ₜ₎}, at the instant of acquisition.

For this purpose, the fourth model M4 is a model able to estimate the value of the steady state voltage Ûₛₜ_{₍ₜ₎} from the voltage value U₍ₜ₎ of the electrochemical element 12 at the instant of acquisition, the current value I₍ₜ₎ of the electrochemical element 12 at the instant of acquisition, and the time elapsed Δₜ_{₍ₜ₎} since the previous instant.

The fourth model M4 is an equivalent electrical model of the system.

In this case, it is a first order RC type electrical model of the electrochemical element 12. In other words, the electrochemical element 12 is assimilated to a first resistor in series with a component, the component being formed of a second resistor and a capacitor. The resistance and capacitance values of these elements are provided by the manufacturer.

Thus, in this case, the method also includes a step for estimating the value of the steady state voltage Ûₛₜ_{₍ₜ₎} at the instant of acquisition, using a model for estimating the steady state voltage, which here is the fourth model M4 in the inference phase.

The fourth model M4 allows to compensate for the fact that the second model M2 performs less well when the voltage of the electrochemical element 12 is highly dynamic.

This poorer performance comes, here, due to the fact that the second model M2 was trained with training data acquired at constant currents.

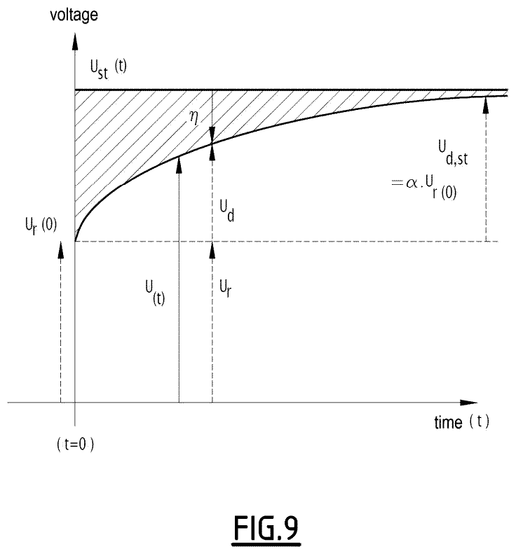

In fact, in the event of a sudden change in current, the fourth model block M4 will generate a voltage Ûₛₜ_{₍ₜ₎} (which is linked to the voltage U₍ₜ₎ and overvoltage η₍ₜ₎, as visible in FIG. 9. This overvoltage η(t) corresponds to the dynamic effects of the voltage U₍ₜ₎ due to a sudden change in current. Removing this voltage allows a smoothed voltage close to constant current to be acquired.

Thus, the fourth M4 model adds the equivalent of a dynamic overvoltage based on the physics of a capacitor. This addition is subject to a current differential trip threshold, in other words, relative to the condition ΔI₍ₜ₎>I_{S}.

What has just been described is now clarified in what follows.

At any given moment, the cell voltage U₍ₜ₎ is broken down into the sum of an instantaneous ohmic term Uᵣ (linked to the cell resistance, given by the manufacturer) and a dynamic term U_{d} (linked to a time constant, given by the manufacturer). This is expressed mathematically as:

$${U}_{( t )} = {U}_{r} ( t ) + {U}_{d} ( t )$$

Under a constant current I₍ₜ₌₀₎ (the one measured at the trip threshold), the dynamic voltage term tends toward a fixed value U_{d,st} at infinity.

The overvoltage η can then be defined as the difference between this term at infinity U_{d,st} and the dynamic term U_{d}.

A variation in the current verifying ΔI₍ₜ₎>I_{S} triggers activation of the fourth model M4. From this point on, the time evolution of the overvoltage will be estimated on from the parameters retained at this threshold, that is, the current I₍ₜ₌₀₎ and the voltage Uᵣ₍ₜ₌₀₎.

The time variation U_{d(t)} of is then estimated via an equivalent electrical model RC of the electrochemical element 12, the discretized equation of which is:

$${U}_{d ( t )} = \frac{{U}_{d , s t} - {U}_{d ( t - 1 )}}{τ} \cdot Δ {t}_{( t )} + {U}_{d ( t - 1 )}$$

Where:
τ is the time constant of electrochemical element 12 in the equivalent model RC, and
U_{d,st}=α·Uᵣ₍ₜ₌₀₎ with α a constant which is the ratio between the dynamic voltage at infinity and the threshold voltage. This ratio is assumed to be constant, depending on the characteristics of electrochemical element 12. The constant α is thus given by the manufacturer of the electrochemical element 12.

The overvoltage η₍ₜ₎ is then written as:

$${η}_{( t )} = {U}_{d ( t )} - α \cdot {U}_{r ( t = 0 )}$$

After a certain time (=3·τ), the overvoltage η₍ₜ₎ tends toward 0 and is considered to be zero. The fourth model M4 is then deactivated. The voltage sent to the second model M2 is then U₍ₜ₎ and not Ûₛₜ_{₍ₜ₎}.

It can be indicated that the fourth model M4 is activated when a current difference threshold between the instant t and the previous instant is reached. Again, this threshold is part of the data from the manufacturer.

Knowing the overvoltage expression, the block output voltage Ûₛₜ_{₍ₜ₎} is estimated as:

$${\hat{U}}_{s {t}_{( t )}} = {U}_{( t )} - {η}_{( t )}$$

This voltage value Uₛₜ₍ₜ₎ approximated by this method allows us to tend toward a voltage value under constant current, a situation for which the second model M2 is specifically trained.

Thus, the dynamic parts associated with a sudden change in current are compensated for by the use of the fourth model M4.

In this embodiment, a better estimation of the state of charge [symbol] , is acquired, which improves the compass correction of the estimation method.

In each embodiment, the second model M2 thus takes as input a voltage value depending on the voltage value acquired from the electrochemical element 12 at the same instant of acquisition.

In the embodiment shown in FIG. 3, the voltage value depending on the voltage value acquired from the electrochemical element 12 at the same instant is the voltage value acquired from the electrochemical element 12 at the same instant of acquisition.

In the embodiment of FIG. 8, the voltage value depending on the voltage value acquired from the electrochemical element 12 at the same instant of acquisition is the estimated steady state voltage value.

Other embodiments may also be considered.

In particular, the coefficient C can be a dynamic coefficient, notably between 1 and 2, which determines the advantageous excursion interval of the coefficient C.

With regard to the threshold, predefined thresholds can also be envisaged, for example by choosing a majorant of the possible values of S depending on the use of the electrochemical element 12.

In each case, the method allows a good estimate of the state of charge SOC of at least one electrochemical element 12 of a battery 10 to be acquired.

1. A method for estimating the state of charge of at least one electrochemical element of a battery,
the method being implemented by a computer, the computer storing a state of charge estimation model estimating from a voltage value, a current value, a temperature value and a capacity value of the at least one electrochemical element the value of the state of charge of the at least one electrochemical element, the state of charge estimation model being a learned neural network,
the method comprising, for a plurality of instants, the steps of:
acquisition of values for the voltage, current, temperature and capacity of the at least one electrochemical element,
calculation of the value of the state of charge of the at least one electrochemical element using a first technique and a second technique,
the first technique comprising the following operations:
acquisition of an estimated value of the state of charge acquired at a previous instant,
calculation of the value of the quantity of charge accumulated since the previous instant, using the acquired current values,
deduction of a first calculated value of the state of charge by calculating the sum of the estimated value of the state of charge acquired at the previous instant and the ratio of the value of the quantity of charge accumulated since the previous instant and the value of the capacity of the at least one electrochemical element,
the second technique comprising the following operations;
application of the state of charge estimation model to the values acquired for the current, the temperature and the capacity of the at least one electrochemical element at the same instant, and to a voltage value depending on the value acquired for the voltage of the at least one electrochemical element at the same instant, to acquire a second calculated state of charge value,
comparison of the difference in absolute value between the second calculated value and the first calculated value with the absolute value of a threshold, and, at least one of: when the difference in absolute value between the second calculated value and the first calculated value is less than or equal to the threshold, determination of the estimated value of the state of charge as being the second calculated value of the state of charge,
or
when the difference in absolute value between the second calculated value and the first calculated value is strictly greater than the threshold, determination of the estimated value of the state of charge, as being the sum of the first calculated value of the state of charge and a correction factor proportional to the threshold.

2. The method for estimating according to claim 1, wherein the correction factor is equal to the product of a coefficient, a direction value and the threshold, the direction value being equal to the ratio between the difference of the second calculated value and the first calculated value and the absolute value of the difference of the second calculated value and the first calculated value.

3. The method for estimating according to claim 1, wherein the threshold depends on the maximum current bias, the maximum current bias taking into account at least one contribution chosen from the list constituted of a first contribution coming from a current sensor providing the current values, a second contribution coming from the self-discharge of the at least one electrochemical element and a third contribution coming from errors on the estimation of the capacity of the at least one electrochemical element.

4. The method for estimating according to claim 3, wherein the method further includes a threshold determination step, the threshold being equal to the ratio between the value of the quantity of charge likely to be accumulated since the previous instant due to the maximum current bias and the value of the capacity of the at least one electrochemical element.

5. The method for estimating according to claim 4, wherein the voltage value depending on the acquired voltage value of the at least one electrochemical element at the same instant of acquisition is the acquired voltage value of the at least one electrochemical element at the same instant of acquisition.

6. The method for estimating according to claim 4, wherein the method further includes a step of estimating the steady state voltage value at the instant of acquisition, the voltage value depending on the acquired voltage value of the at least one electrochemical element at the same instant of acquisition being the estimated steady state voltage value.

7. The method for estimating according to claim 6, wherein the estimation step is implemented by applying a steady state voltage estimation model to the voltage value of the at least one electrochemical element at the instant of acquisition, the current value of the at least one electrochemical element at the instant of acquisition and the time elapsed since the previous instant.

8. The method for estimating according to claim 1, wherein the neural network is a multilayer perceptron.

9. The method for estimating according to claim 1, wherein the neural network includes a number of neurons less than or equal to 100.

10. The method for estimating according to claim 1, wherein the initial estimated value of the state of charge is chosen from among the predefined values and the second calculated value.

11. The method for estimating according to claim 1, wherein the at least one electrochemical element presents a state of charge open circuit voltage characteristic with a flat portion, a flat portion being a portion wherein the open circuit voltage variation is less than 30 mV for a variation of at least 10% in the state of charge.

12. The method for estimating according to claim 1, wherein the at least one electrochemical element comprises a cathode active material chosen from among the following groups or mixtures thereof:
i) a compound of the formula LiₓFe_{1-y}M_{y}PO₄ where M is chosen from the group consisting of B, Mg, Al, Si, Ca, Ti, V, Cr, Mn, Co, Ni, Cu, Zn, Y, Zr, Nb and Mo; and 0.8≤x≤1.2; 0≤y≤0.6, ii) a compound of formula LiₓMn_{1-y-z}M′_{y}M″_{z}PO₄, where M′ and M″ are different from each other and are chosen from the group consisting of B, Mg, Al, Si, Ca, Ti, V, Cr, Fe, Co, Ni, Cu, Zn, Y, Zr, Nb and Mo, with 0.85≤x≤1.2; 0≤y≤0.6; 0.0≤z≤0.2,
iii) a compound of formula LiₓMn_{2-y-z}Ni_{y}M₂O_{4-d-c}F_{c} where M represents one or more elements chosen from the group consisting of B, Mg, Al, Si, Ca, Ti, V, Cr, Fe, Co, Cu, Zn, Y, Zr, Nb, Ru, W and Mo; and 1≤x≤1.4; 0<y≤0.6; 0≤z≤0.2; 0≤d≤1; 0≤c≤1,
iv) a compound of the formula LiₓMn_{2-y-z}M′_{y}M″_{z}O₄, where M′ and M″ are chosen from the group consisting of B, Mg, Al, Si, Ca, Ti, V, Cr, Fe, Co, Ni, Cu, Zn, Y, Zr, Nb and Mo; M′ and M″ being different from each other, and 1≤x≤1.4; 0≤y≤0.6; 0≤z≤0.2, and
v) a compound of the formula LiVPO₄F.

13. A computer able to estimate the state of charge of at least one electrochemical element of a battery,
the computer storing a state of charge estimation model estimating from a voltage value, a current value, a temperature value and a capacity value of the at least one electrochemical element the value of the state of charge of the at least one electrochemical element, the state of charge estimation model being a learned neural network,
the computer being able to:
acquire the values for the voltage, the current, the temperature and the capacity of the at least one electrochemical element,
calculate the value of the state of charge of the at least one electrochemical element according to a first technique and a second technique,
the first technique including the following operations:
acquisition of an estimated value of the state of charge acquired at a previous instant,
calculation of the value of the quantity of charge accumulated since the previous instant, using the current values acquired,
deduction of a first calculated value of the state of charge by calculation of the sum of the estimated value of the state of charge acquired at the previous instant and the ratio of the value of the quantity of charge accumulated since the previous instant and the value of the capacity of the at least one electrochemical element,
the second technique including the following operations:
application of the state of charge estimation model to the values acquired for the current, temperature and capacity of the at least one electrochemical element at the same instant of acquisition, and to a voltage value dependent on the value acquired for the voltage of the at least one electrochemical element at the same instant of acquisition, to acquire a second calculated value for the state of charge, and
comparison of the difference in absolute value between the second calculated value and the first calculated value and a threshold, and
when the difference in absolute value between the second calculated value and the first calculated value is less than or equal to the threshold, determine the estimated value of the state of charge as being the second calculated value of the state of charge,
or
when the difference in absolute value between the second calculated value and the first calculated value is strictly greater than the threshold, determine the estimated value of the state of charge, as being the sum of the first calculated value of the state of charge and a correction factor proportional to the threshold.

14. A management system for at least one electrochemical element of a battery, the at least one electrochemical element presenting terminals, the management system comprising:
a voltage sensor able to measure the voltage at the terminals of said at least one electrochemical element,
a current sensor able to measure the current delivered by said at least one electrochemical element,
a temperature sensor able to measure the temperature of said at least one electrochemical element, and
a computer according to claim 13.

15. A battery comprising:
at least one electrochemical element, and
a management system according to claim 14.
